(19) United States
(12) Patent Application Publication
(10) Pub. No.: US 2010/0136215 A1
(43) Pub. Date: Jun. 3, 2010

(54) METHOD FOR FORMING FERRITE FILM ONTO SURFACE OF STRUCTURAL MEMBER COMPOSING PLANT, FERRITE FILM FORMATION APPARATUS AND QUARTZ CRYSTAL ELECTRODE APPARATUS

(75) Inventors: Tsuyoshi ITO, Hitachi (JP); Hideyuki HOSOKAWA, Hitachinaka (JP); Yukio HIRAMA, Mito (JP); Makoto NAGASE, Mito (JP)

Correspondence Address: MATTINGLY & MALUR, P.C., 1800 DIAGONAL ROAD, SUITE 370, ALEXANDRIA, VA, 22314, US

(73) Assignee: HITACHI-GE NUCLEAR ENERGY, LTD., Ibaraki (JP)

(21) Appl. No.: 12/619,806

(22) Filed: Nov. 17, 2009

(30) Foreign Application Priority Data
Nov. 28, 2008 (JP) 2008-303323

(51) Int. Cl. C23C 16/52; B05C 11/00

(52) U.S. Cl. 427/8; 118/712; 118/708

(57) ABSTRACT

A method for forming a ferrite film onto surface of structural member composing a plant, comprises steps of forming a ferrite film onto the wetted surface of the structural member by making contact with a film forming solution containing iron (II) ions, an oxidant for oxidizing the iron (II) ions, and a pH adjustment agent; measuring the amount of the formed ferrite film; and determining completion of the ferrite film formation based on the measured amount of the formed ferrite film. The method for forming the ferrite film onto the surface of the structural member, can shorten the time required for completing the ferrite film forming operations.

### CLAIM OF PRIORITY

The present application claims priority from Japanese Patent application serial no. 2008-303323, filed on Nov. 28, 2008, the content of which is hereby incorporated by reference into this application.

### BACKGROUND OF THE INVENTION

The present invention relates to a method for forming a ferrite film onto surface of structural member composing a plant, a ferrite film formation apparatus and quartz crystal electrode apparatus and, more particularly, to a method for forming a ferrite film onto surface of structural member composing a plant, a ferrite film formation apparatus and a quartz crystal electrode apparatus, suitable for a boiling water reactor plant.

As a nuclear power plant, for example, a boiling water reactor plant (hereinafter referred to as BWR plant) and a pressurized water reactor plant (hereinafter referred to as PWR plant) are known. A BWR plant, for example, has a nuclear reactor with a core in a reactor pressure vessel (hereinafter referred to as RPV). Cooling water supplied to the core by a recirculation pump (or an internal pump) to the core is heated by heat generated due to nuclear fission of nuclear fuel material in fuel assemblies loaded in the core. A part of the heated cooling water becomes steam. This steam is introduced from the nuclear reactor to a turbine to turn the turbine. The steam exhausted from the turbine is condensed in a condenser, producing water. This water is supplied to the nuclear reactor as feed water. To suppress generation of radioactive corrosion products in the nuclear reactor, a demineralizer disposed in a feed water pipe mainly removes metal impurities from the feed water.

In nuclear power plants such as a BWR plant and a PWR plant, stainless steel or nickel base alloy are used for a main structural member, with which the cooling water is contacted, such as the reactor pressure vessel, to suppress corrosion. For the other structural members such as a reactor water clean-up system, a residual heat removal system, a reactor core isolation cooling system, a core spray system, a feed water system, and a condensate water system, carbon steel members are mainly used in view of reducing the necessary cost of building the plant and of avoiding the stress corrosion cracking of stainless steel caused by high-temperature water flowing in the feed water system and the condensate water system.

Unfortunately, the carbon steel members composing the reactor water clean-up system, the residual heat removal system, the reactor core isolation cooling system, the core spray system, the feed water system, and the condensate water system also have a wetted surface with which the water is contacted, and the wetted surfaces may corrode. In this case, if the carbon steel member is disposed downstream of a clarification apparatus as the demineralizer, corrosion products from the carbon steel member may cause radioactive corrosion products in the nuclear reactor. Furthermore, the corrosion products from the carbon steel member may cause a decrease in heat exchange efficiency of a secondary system in the PWR plant.

Consequently, in order to suppress corrosion of a carbon steel member composing a nuclear power plant, it was done to propose a method for forming a closely packed ferrite film (for example, a magnetite film or a nickel ferrite film) onto a wetted surface of the carbon steel member (for example, see Japanese Patent Laid-open No. 2007-182604). In the ferrite film formation, a film forming solution is used. This film forming solution contains a first agent including iron (II) ions, a second agent (an oxidant) for oxidizing the iron (II) ions into iron (III) ions, and a third agent (a pH adjustment agent) for adjusting the pH. The ferrite film serves as a protective film for blocking the cooling water from contacting the carbon steel member, which suppresses corrosion of the wetted surface of the structural member suitable for a nuclear power plant.

Japanese Patent Laid-open No. 2006-38483 discloses a method for forming a closely packed ferrite film onto a wetted surface of a stainless steel member (for example, the inner surface of a recirculation pipe of a BWR plant) to suppress deposition of radionuclides onto the wetted surface of the stainless steel member, which is a structural member of a nuclear power plant. In this ferrite film formation as well, the above-described film forming solution including the first agent containing the iron (II) ions, the second agent for oxidizing the iron (II) ions into iron (III) ions, and the third agent for adjusting the pH is used.

### SUMMARY OF THE INVENTION

When forming closely packed ferrite films onto the wetted surface of a carbon steel member and a stainless steel member, it is important to check whether the ferrite film is formed in a predetermined thickness onto each the wetted surface in view of suppressing corrosion of the carbon steel member and of suppressing deposition of radionuclides on the stainless steel member of a nuclear plant. Japanese Patent Laid-open No. 2007-182604 and Japanese Patent Laid-open No. 2006-38483 fail to mention about checking the thickness of the ferrite film formed.

In order to check the thickness of a ferrite film formed onto a structural member, for example, the inner surface of a pipe in a nuclear plant, a test piece made of the same material as the pipe may be used. A method for checking the thickness of this ferrite film will be explained. The test piece is, for example, disposed through a branching pipe inside a treatment solution feed pipe of a ferrite film forming apparatus connected to the pipe on which a ferrite film is to be formed. Then, a film forming solution containing the first agent, the second agent, and the third agent is supplied through the treatment solution feed pipe to the pipe on which the ferrite film is to be formed. Since this film forming solution contacts not only the inner surface of the pipe on which the ferrite film is to be formed, but also a surface of the test piece, the ferrite film is formed on the surface of the test piece as well. When the time elapsed since the beginning of the film forming solution supply reached the time needed for forming the ferrite film of a predetermined thickness, known from experience, the supply of the film forming solution is stopped and the test piece is taken out from the branching pipe. The weight of the taken out test piece is measured, and the thickness of the ferrite film formed on the inner surface of the pipe is estimated based on a change in weight since the test piece was first disposed in the branching pipe.

Unfortunately, the inventors have found out that the following two problems arose when the thickness of the ferrite film formed on the surface of a structural member of a nuclear power plant was estimated on the basis of a change in weight of the test piece: (1) When the ferrite film formation has failed or when the amount of the ferrite film formation has not reached a predetermined amount, the test piece must be soaked in the film forming solution again and supply of the film forming solution for forming the ferrite film must be restarted. For this reason, a series of procedures for forming the ferrite film must be repeated, which requires more time for forming the ferrite film of the predetermined thickness. (2) Even when the ferrite film of the target predetermined thickness is formed in a short period of time, the film forming solution must be supplied to the pipe on which the ferrite film is to be formed, for a set period of time known from experience. In this case, the time after the ferrite film of the predetermined thickness has formed is wasted.

From the above problems, the inventors came to realize a need for reducing the time required for the ferrite film formation.

An object of the present invention is to provide a method for forming a ferrite film onto surface of structural member composing a plant, a ferrite film formation apparatus and quartz crystal electrode apparatus, which can shorten the time required for completing a ferrite film forming operations.

The present invention to achieve the above object is characterized in that amount of formed ferrite film is measured, and completion of the ferrite film formation is determined based on the measured amount of the formed ferrite film.

Since the completion of the ferrite film formation is determined based on the measured amount of the ferrite film formation, end of the ferrite film forming operations on a film-forming object can be more accurately determined. This can shorten the time required from the start to the end of the ferrite film forming operations.

The above object can also be achieved by measuring the amount of the formed ferrite film, and stopping the injections of agent containing iron (II) ions, and an oxidant into a film forming solution based on the measured amount of the formed ferrite film.

The injection amounts of the agent containing the iron (II) ions, and an oxidant into film forming solution are controlled based on measured amount of formed ferrite film. This allows a set amount of a magnetite film to be formed in a shorter period of time.

According to the present invention, the time required for completing the ferrite film forming operations can be shortened.

### BRIEF DESCRIPTION OF THE DRAWINGS

FIG. 1, is flowchart showing a processing procedure being carried out in a method for forming a ferrite film onto a surface of a structural member composing a nuclear power plant according to Embodiment 1 which is a preferred embodiment of the present invention, applied to a recirculation pipe in a BWR plant.

FIG. 2 is an explanatory drawing showing a status in which a film formation apparatus used as the method for forming a ferrite film shown in FIG. 1 is connected to a recirculation pipe in a BWR plant.

FIG. 3 is a detailed structural diagram showing the film formation apparatus shown in FIG. 2.

FIG. 4 is an explanatory drawing showing in detail a status in which a quartz crystal electrode apparatus shown in FIG. 3 is attached to a film-forming solution pipe shown in FIG. 3.

FIG. 5 is a characteristic diagram showing measurement results of weight changes measured by an existing quartz crystal electrode apparatus soaked in pure water at 90° C.

FIG. 6 is a longitudinal sectional view showing an existing quartz crystal electrode apparatus.

FIG. 7 is a longitudinal sectional view showing a modified quartz crystal electrode apparatus.

FIG. 8 is a characteristic diagram showing measurement results of weight changes measured by a quartz crystal electrode apparatus shown FIG. 7 soaked in pure water at 90° C.

FIG. 9 is a characteristic diagram showing a change in a weight gain of film during ferrite film formation, measured by a quartz crystal electrode apparatus shown in FIG. 7.

FIG. 10 is a characteristic diagram showing a laser Raman spectrum of a surface of a structural member on which surface a ferrite film is formed.

FIG. 11 is a detailed structural diagram sowing a film formation apparatus used for a method for forming a ferrite film onto a surface of a structural member composing a nuclear power plant according to Embodiment 2 which is another embodiment of the present invention, applied to a recirculation pipe in a BWR plant.

FIG. 12 is a detailed structural diagram sowing a film formation apparatus used for a method for forming a ferrite film onto a surface of a structural member composing a nuclear power plant according to Embodiment 3 which is another embodiment of the present invention, applied to a recirculation pipe in a BWR plant.

FIG. 13 is a flowchart showing a processing procedure being carried out in a method for forming a ferrite film onto a surface of a structural member composing a nuclear power plant according to Embodiment 3 by using a film formation apparatus shown in FIG. 12.

FIG. 14 is an explanatory drawing showing a status in which a film formation apparatus is connected to a clean-up pipe in the method for forming a ferrite film onto a surface of a structural member composing a nuclear power plant according to Embodiment 4 which is another embodiment of the present invention, applied to a clean-up pipe in a BWR plant.

### DETAILED DESCRIPTION OF THE PREFERRED EMBODIMENTS

The inventors have studied to find a method for forming a ferrite film onto a surface of a structural member composing a nuclear power plant, which can shorten the time required for completing a ferrite film forming operation. The results of the study will be described below.

The inventors have tackled a problem, namely, whether or not thickness of a ferrite film formed on an inner surface of a pipe on which the ferrite film is to be formed, can be measured while supplying a film forming solution to the pipe. For solving this problem, the inventors pay attention to a technology called Quartz Crystal Microbalance method (hereinafter referred to as “QCM”). QCM is a technology for continuously measuring a microscopic weight in an aqueous solution at a temperature of 60° C. or lower.

In the method for forming a ferrite film onto a surface of a structural member composing a nuclear power plant, temperature of a film forming solution supplied to a pipe on which the ferrite film is to be formed, must be a temperature in the range of 60° C. to 100° C. Preferably, the temperature of the film forming solution is adjusted to 90° C. No examples exist in which, the QCM is applied to such a high-temperature liquid.

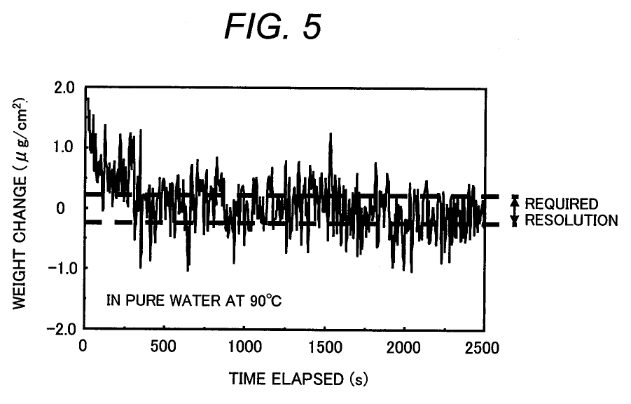

The inventors, thus, have studied whether the QCM can be applied to the ferrite film formation on a surface of a structural member composing a nuclear power plant. An existing quartz crystal electrode apparatus adopting the QCM to be used in a liquid at 60° C. or lower was soaked in pure water at 90° C., and the magnitude of noise was measured. In this measurement, a existing quartz crystal electrode apparatus that guarantees a resolution of 0.15 (μg/cm²) at 60° C. or lower was used, which resolution was necessary for closely measuring the initial weight change in the ferrite film formation. The result of the measurement using the quartz crystal electrode apparatus is shown in FIG. 5. Unfortunately, the existing quartz crystal electrode system yielded too much noise to meet the required resolution.

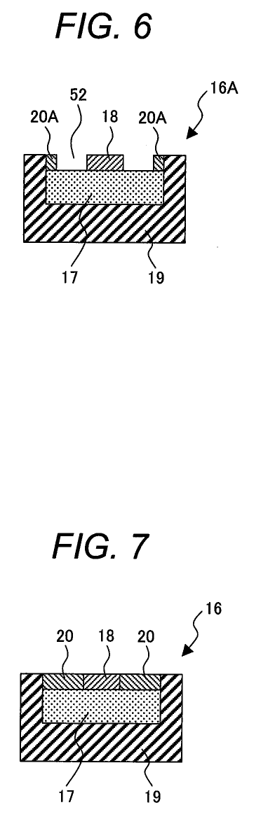

The inventors have in detail studied the cause of the measurement results shown in FIG. 5 yielded by the existing quartz crystal electrode apparatus in the pure water at 90° C. A existing quartz crystal electrode apparatus 16A, as shown in FIG. 6, has a quartz crystal 17, a metal member 18, and an electrode holder 19. The quartz crystal 17 is disposed in a hollow of the electrode holder 19, and the metal member 18 is installed on a surface of the quartz crystal 17, not contacting the electrode holder 19. The metal member 18 is made of the same material as a structural member composing a nuclear power plant (for example, stainless steel or carbon steel). A sealing member 20A is disposed on this surface around the quartz crystal 17 along an inner surface of the electrode holder 19. This sealing member 20A prevents water (or an aqueous solution) contacting the metal member 18 from leaking in between a side of the quartz crystal 17 and the electrode holder 19. An annular opening 52 is formed between the sealing member 20A and the metal member 18.

The inventors have found out that because the opening 52 was formed in the existing quartz crystal electrode apparatus 16A having the above structure, the quartz crystal electrode apparatus 16A showed the property shown in FIG. 5 in the pure water at 90° C. That is, in the quartz crystal electrode apparatus 16A, since the pure water in the opening 52 contacts with both the quartz crystal 17 and the metal member 18, the noise is caused to increase in the pure water at 90° C. Considering this result, the inventors have devised a quartz crystal electrode apparatus 16 having a new structure shown in FIG. 7. In this modified quartz crystal electrode apparatus 16, the sealing member 20 covers an entire surface of the quartz crystal 17 disposed in the hollow of the electrode holder 19, the entire surface other than the surfaces contacting the metal member 18 and the electrode holder 19. Since the quartz crystal electrode apparatus 16 forms no opening 52 as the quartz crystal electrode apparatus 16A, the quartz crystal 17 has no contact with the pure water (or the aqueous solution) contacting a surface of the metal member 18, due to the sealing member 20.

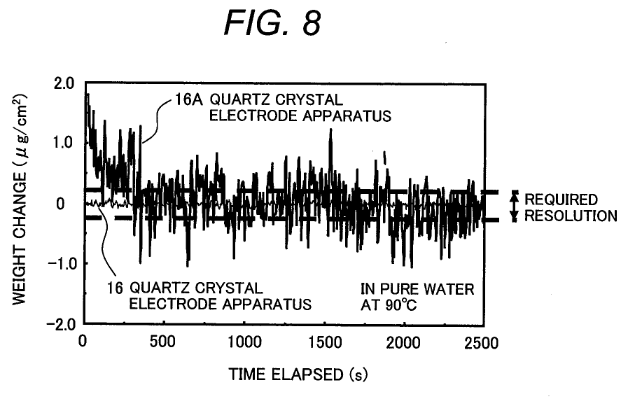

Changes in weight are measured using the quartz crystal electrode apparatus 16 soaked in the pure water at 90° C. The results of the measurement are shown in FIG. 8. In this measurement results measured by the quartz crystal electrode apparatus 16, the changes in weight were practically 0 in the pure water that contained nearly no impurities depositable on a surface of the metal member 18, and the measurements stayed in a range of necessary resolution. Using the quartz crystal electrode apparatus 16, the noise was significantly reduced compared to the quartz crystal electrode apparatus 16A, and this made measurements in the pure water at a high temperature of 90° C. possible.

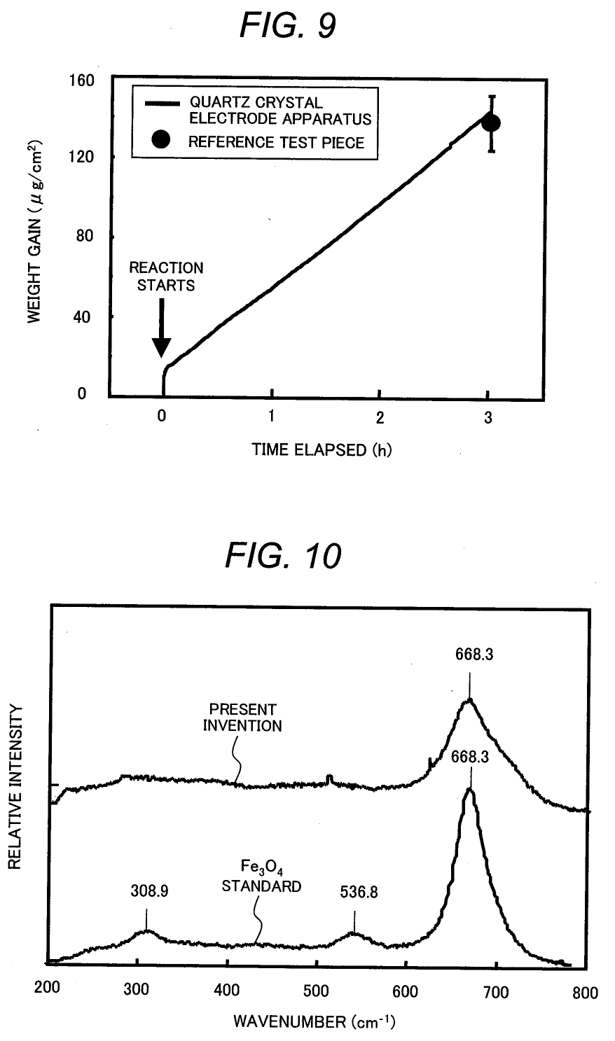

The experiment of continuously measuring the amount of formed ferrite film was conducted using the quartz crystal electrode apparatus 16 devised by the inventors. A stainless steel member was used for the metal member 18 of the quartz crystal electrode apparatus 16 in this experiment. A stainless steel test piece (a reference test piece) was soaked in a film forming solution containing the previously-described first, second, and third agents, along with the quartz crystal electrode apparatus 16 to compare the metal member with stainless steel which constitutes a structural member composing a nuclear power plant, in the amount of the ferrite film formed on their surfaces. The measurement results in this experiment using the quartz crystal electrode apparatus 16 are shown in FIG. 9. A ferrite film was formed on the surface of the metal member (stainless steel) 18 of the quartz crystal electrode apparatus 16, contacting the film forming solution, and the weight of the metal member 18 increased. The weight of the metal member 18, as shown in FIG. 9, rapidly gained in the beginning, and increased in a linear manner afterward. The stainless steel test piece was taken out from the film forming solution when three hours have elapsed after the quartz crystal electrode apparatus 16 and the stainless steel test piece had been simultaneously soaked in the film forming solution, then weight gain of the stainless steel test piece was measured. The measured weight gain of the stainless steel test piece is shown as a black dot in FIG. 9. The measured weight gain of the stainless steel test piece and the weight gain of the metal member 18 measured by the quartz crystal electrode apparatus 16 three hours after they have been soaked in the film forming solution were in a reasonable agreement with each other. The weight gains of the two were in agreement with a margin of error of 15%. Thus, based on the measurement results by the quartz crystal electrode apparatus 16, it became clear that it was possible to measure the amount of a formed ferrite film onto the surface of a stainless steel member which is a structural member composing a nuclear plant, contacting a film forming solution. By measuring the amount of the formed ferrite film using the quartz crystal electrode apparatus 16, whether the ferrite film of a predetermined amount (a predetermined thickness) is formed on a surface of a structural member composing a nuclear power plant or not can be effectively checked. Accordingly, it is possible to properly determine when to end the ferrite film forming operations.

If the metal member 18 is made larger to increase its surface area contacting the film forming solution, the flow of the film forming solution makes the quartz crystal 17 adversely vibrate through the metal member 18. This increases the frequency of the quartz crystal 17, and the measurement result shows as if the amount of the formed ferrite film on the surface of the metal member 18 had increased. To avoid such an increase in noise, the size of the metal member 18 must be appropriately set.

A Raman spectrum of the ferrite film formed on the surface of the metal member 18 was measured. FIG. 10 shows the results of the measurement of the Raman spectrum. As shown in FIG. 10, the Raman spectrum of the ferrite film formed on the surface of the metal member 18 according to the present invention corresponds to the standard spectrum of magnetite (Fe₃O₄). From the results described above, the film formed on the surface of the metal member 18 of the quartz crystal electrode apparatus 16 was confirmed to be a magnetite (Fe₃O₄) film.

In a theory of crystal growth in an aqueous solution, the velocity of film formation on a surface of a structural member is represented as Equation (1).

V=KN(α) (1)

Here, K is impurity coefficient of an aqueous solution, N is material transfer coefficient, and α is supersaturation ratio. Thus, the thickness of a ferrite film formed on a surface of a structural member composing a nuclear power plant can be estimated by calculating the velocity of the ferrite film formation based on a measured weight change. The supersaturation ratio α is determined by the amount of agents injected into a film forming solution during the ferrite film formation. For this reason, when the velocity of the ferrite film formation is slow, the amount of agents injected into the film forming solution can be adjusted to raise the supersaturation ratio α and consequently to increase the velocity of the ferrite film formation.

Preferably, the quartz crystal electrode apparatus 16 is disposed in a film-forming solution pipe of a film formation apparatus connected to a pipe being a ferrite film-forming object, in a nuclear plant. When the pipe on inner surface of which a ferrite film is to be formed is a recirculation pipe in a BWR plant, a stainless steel member constituting the recirculation pipe is used for the metal member 18, and when the pipe on which the ferrite film is to be formed is a reactor water clean-up pipe in a BWR plant, a carbon steel member constituting the reactor water clean-up pipe is used for the metal member 18. The quartz crystal electrode apparatus 16 can be used for forming a ferrite film on the inner surface of a pipe in a PWR plant as well.

Various embodiments of the method for forming a ferrite film onto a surface of a structural member composing a nuclear power plant according to the present invention, reflecting the above results of the study done by the inventors will be described below.

### Embodiment 1

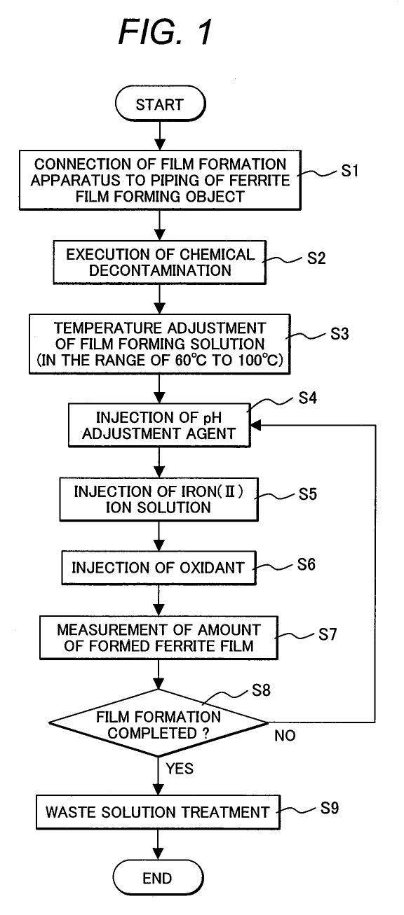

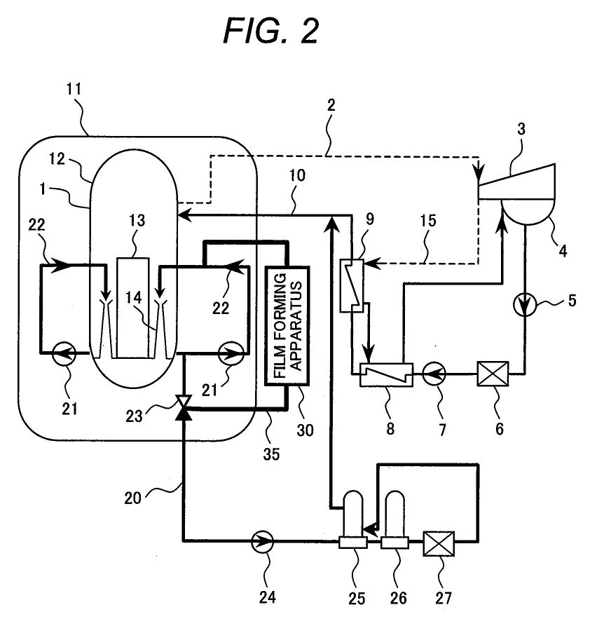

As a preferred embodiment of the present invention, the method for forming a ferrite film onto a surface of a structural member composing a nuclear power plant, applied to a recirculation pipe of a BWR plant, according to embodiment 1 is described below with reference to FIGS. 1, 2, and 3.

A BWR plant, which is a nuclear power generation plant, has a nuclear reactor 1, a turbine 3, a condenser 4, a recirculation system, a reactor clean-up system, a feed water system, and so on. The nuclear reactor 1 has a reactor pressure vessel (hereinafter referred to as RPV) 12 in which a core 13 is disposed, and jet pumps 14 disposed in the RPV 12. A plurality of fuel assemblies (not shown) are loaded in the core 13. The fuel assembly has a plurality of fuel rods filled with a plurality of fuel pellets made from nuclear fuel material. The recirculation system has a recirculation pipe 22 and a recirculation pump 21 installed to the recirculation pipe 22. In the feed water system, a condensate pump 5, a condensate clean-up apparatus 6, a feed water pump 7, low pressure feed water heaters 8, and high pressure feed water heaters 9 are installed in this order to a feed water pipe 10 communicating with the condenser 4 and the RPV 12. In the reactor clean-up system, a clean-up pump 24, a regenerative heat exchanger 25, a non-regenerative heat exchanger 26, and a reactor water clean-up apparatus 27 are installed in this order to a clean-up pipe 20 communicating with the recirculation pipe 22 and the feed water pipe 10. The clean-up pipe 20 is connected to the recirculation pipe 22 upstream of the recirculation pump 21. The nuclear reactor 1 is installed in a primary containment vessel 11 disposed in a reactor building (not shown).

Cooling water inside the RPV 12 is pressurized by the recirculation pump 21, and ejected into the jet pump 14 through the recirculation pipe 22. The cooling water around a nozzle of the jet pump 14 is also sucked into the jet pump 14 and supplied to the core 13. The cooling water supplied to the core 13 is heated using the heat generated by nuclear fission of the nuclear fuel material in the fuel rods. A part of the heated cooling water turns into steam. This steam is introduced from the RPV 12 into the turbine 3 through a main steam pipe 2 to turn the turbine 3. A power generator (not shown) coupled to the turbine 3 rotates to generate power. The steam exhausted from the turbine 3 is condensed by the condenser 4 and turns into water. This water is supplied as feed water into the RPV 12 through the feed water pipe 10. The feed water flowing though the feed water pipe 10 is pressurized by the condensate pump 5, impurities included in the feed water are removed by the condensate clean-up apparatus 6, and the feed water is further pressurized by the feed water pump 7. The feed water pressurized by the feed water pump 7 is heated by the low pressure feed water heaters 8 and the high pressure feed water heaters 9 and introduced into the RPV 12. Extraction steam extracted from the turbine 3 and the main steam pipe 2 is supplied to each of the low pressure feed water heaters 8 and the high pressure feed water heaters 9 through bleeding pipes 15, and becomes a heat source for the feed water.

A part of the cooling water flowing in the recirculation pipe 22 is introduced into the clean-up pipe 20 by operation of the clean-up pump 24, and after being cooled by the regenerative heat exchanger 25 and the non-regenerative heat exchanger 26, it is cleaned up by the water clean-up apparatus 27. The cleaned-up cooling water is heated by the regenerative heat exchanger 25 and returned to the RPV 12 through the clean-up pipe 20 and the feed water pipe 10.

After the operation of a BWR plant is shut down for an annual inspection of the BWR plant, one end of a film-forming solution pipe (a circulation pipe) 35 of a film formation apparatus 30, which is temporary equipment, is connected to the clean-up pipe 20, and the other end of the film-forming solution pipe 35 is connected to the recirculation pipe 22. To be more specific, a bonnet of a valve 23 installed on the clean-up pipe 20 connected to the recirculation pipe 22 is opened, and the reactor water clean-up system 27 side of the bonnet is closed. One end of the film-forming solution pipe 35 is connected to a flange of the valve 23. With such operations, the film-forming solution pipe 35 is connected to the recirculation pipe 22 upstream of the recirculation pump 21 through a part of the clean-up pipe 20. The other end of the film-forming solution pipe 35 is connected to a drain pipe (or an instrumentation pipe) connected to the recirculation pipe 22 downstream of the recirculation pump 21. Therefore, the film formation apparatus 30 is connected to the recirculation pipe 22 on the inner surface of which a ferrite film is to be formed. By connecting the film-forming solution pipe 35 in the above way, a circulation flow passage for the film forming solution is formed, connecting the film-forming solution pipe 35, a part of the clean-up pipe 20, the recirculation pipe 22, and the film-forming solution pipe 35.

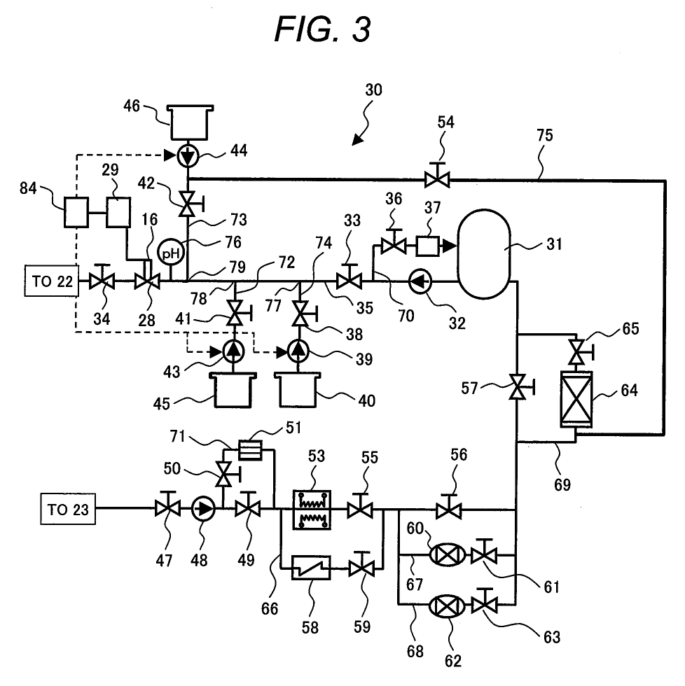

A detailed structure of the film formation apparatus 30 will be described with reference to FIG. 3. The film formation apparatus 30 has a surge tank 31, the film-forming solution pipe 35, bath tanks 40, 45, and 46, a filter 51, a decomposition apparatus 64, and a cation resin tower 60. An opening/closing valve 47, a circulation pump 48, a valve 49, a heater 53, valves 55, 56, and 57, the surge tank 31, a circulation pump 32, a valve 33, and an opening/closing valve 34 are provided to the film-forming solution pipe 35 in this order from the upstream end. The valve 50 and the filter 51 are installed to a pipe 71 connected to the film-forming solution pipe 35, bypassing the valve 49. A pipe 66 bypassing the heater 53 and the valve 55 is connected to the film-forming solution pipe 35. A cooler 58 and a valve 59 are installed to the pipe 66. The cation resin tower 60 and a valve 61 are installed to a pipe 67 bypassing the valve 56; both ends of the pipe 67 are connected to the film-forming solution pipe 35. A mixed resin tower 62 and a valve 63 are installed to a pipe 68 bypassing the cation resin tower 60 and the valve 61; both ends of the pipe 68 are connected to the pipe 67.

A valve 65 and the decomposition apparatus 64 are installed to a pipe 69 that bypasses the valve 57 and is connected to the film-forming solution pipe 35. The decomposition apparatus 64 is filled with, for example, active carbon catalysts that were made by adhering ruthenium to surface of active carbon, inside. The surge tank 31 is installed to the film-forming solution pipe 35 between the valve 57 and the circulation pump 32. A pipe 70 provided with a valve 36 and an ejector 37 is connected to the film-forming solution pipe 35 between the valve 33 and the circulation pump 32, and is further connected to the surge tank 31. A hopper (not shown) is provided to the ejector 37 to supply the surge tank 31 with KMnO₄ (an oxidation decontamination agent) used for oxidation dissolution of the inner surface of the recirculation pipe 22 on which a ferrite film is formed, and in addition, with oxalic acid (a reduction decontamination agent) used for reduction dissolution of contaminations in the recirculation pipe 22.

An iron (II) ion injection apparatus has the bath tank 45, an injection pump 43, and an injection pipe 72. The bath tank 45 is connected to the film-forming solution pipe 35 through the injection pipe 72 having the injection pump 43 and a valve 41. The bath tank 45 is filled with an agent containing divalent iron (II) ions prepared by dissolving iron in formate acid. This agent contains formate acid. The agent for dissolving iron is not limited to formate acid, but organic acid or carbonic acid, having counter-anions to iron (II) ions, may be used. An oxidant injection apparatus has the bath tank 46, an injection pump 44, and an injection pipe 73. The bath tank 46 is connected to the film-forming solution pipe 35 through the injection pipe 73 having the injection pump 44 and a valve 42. The bath tank 46 is filled with hydrogen peroxide, which is an oxidant. A pH adjustment agent injection apparatus has the bath tank 40, an injection pump 39, and an injection pipe 74. The bath tank 40 is connected to the film-forming solution pipe 35 through the injection pipe 74 having the injection pump 39 and a valve 38. The bath tank 40 is filled with hydrazine, which is a pH adjustment agent.

In the present invention, a first connection point 77 of the pH adjustment agent injection apparatus to the film-forming solution pipe 35 (the connection point of the injection pipe 74 and the film-forming solution pipe 35) is located at the uppermost point among the first connection point 77, a second connection point 78 of the iron (II) ion injection apparatus to the film-forming solution pipe 35 (the connection point of the injection pipe 72 and the film-forming solution pipe 35), and a third connection point 79 of the oxidant injection apparatus to the film-forming solution pipe 35 (the connection point of the injection pipe 73 and the film-forming solution pipe 35). The second connection point 78 is located downstream of the first connection point 77, and the third connection point 79 is located downstream of the second connection point 78. Preferably, on the film-forming solution pipe 35, the third connection point 78 is positioned as close as possible to the object region for chemical decontamination and ferrite film formation. A pipe 75 provided with a valve 54 connects the pipe 73 and the pipe 69. The surge tank 31 is filled with water for treatment. In order to remove oxygen contained in the film forming solution, bubbling of an inert gas such as nitrogen or argon in the bath tank 45 and the surge tank 31 is preferred.

The decomposition apparatus 64 can resolve organic acid (for example, formate acid) used as counter-anions to the iron (II) ions, and hydrazine that is a pH adjustment agent. That is, as counter-anions to the iron (II) ions, organic acid which can be resolved into water or carbon dioxide, or carbonic acid that can be released as gas to decrease waste is used in consideration of waste reduction. The decomposition apparatus 64 can also resolve organic acid (for example, oxalic acid) used for the process of reduction decontamination.

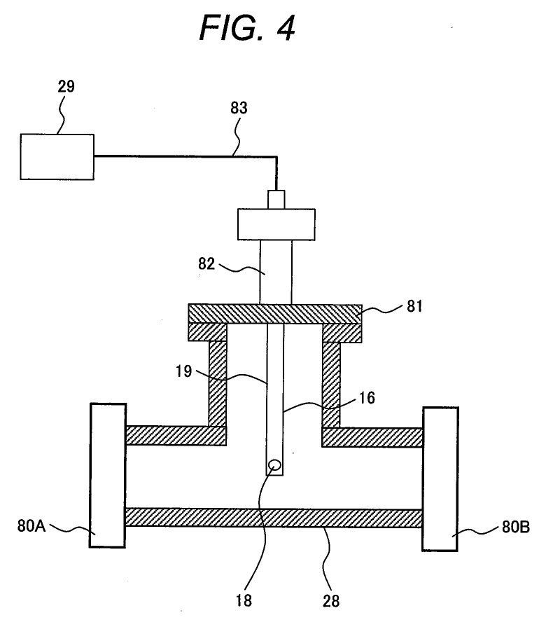

A film-thickness measuring apparatus (a film-forming amount measurement apparatus) has the previously described quartz crystal electrode apparatus 16, and a film-thickness calculation apparatus (a film-forming amount calculation apparatus) 29 (see FIG. 4). A metal member 18 of the quartz crystal electrode apparatus 16 is made of stainless steel constituting the recirculation pipe 22, which is a structural member composing a BWR plant. An installation structure of the quartz crystal electrode apparatus 16 to the film-forming solution pipe 35 is described in detail with reference to FIG. 4. A valve bonnet 28 in which a valve disc was removed, is installed to the film-forming solution pipe 35 downstream of the third connection point 79. To be more specific, flanges 80A of the valve bonnet 28 are connected to the film-forming solution pipe 35. The quartz crystal electrode apparatus 16 is disposed inside the valve bonnet 28. A long-extending electrode holder 19 of the quartz crystal electrode apparatus 16 is installed to a flange 81 fixed to the valve bonnet 28, using a feed-through 82. Two wirings 83 passing through the electrode holder 19 are connected to a quartz crystal 17. These wirings 83 are connected to the film-thickness calculation apparatus 29.

In the quartz crystal electrode apparatus 16, the metal member 18 is directly installed to the quartz crystal 17. However, the surface of the quartz crystal 17 may be covered with oxide such as TiO₂, and on which oxide, the metal member 18 may be installed by vapor deposition. If the metal member, being an alloy such as stainless steel, is too difficult to fix to the quartz crystal 17, Au or Pt may be fixed to the quartz crystal 17 as a substitute.

The method for forming a ferrite film according to the present embodiment is described in detail with reference to FIG. 1. First, the film formation apparatus 30 is connected to a film-forming object piping (step S1). After the operation of a BWR plant is shut down for an annual inspection of the BWR plant, the film-forming solution pipe 35 is, as described above, connected to the recirculation pipe 22 that is the film-forming object piping.

Chemical decontamination is carried out for the film-forming object region (step S2). An oxidized film containing radionuclides is formed on the inner surface of the recirculation pipe 22 contacting the cooling water from the RPV 12. Although the purpose of forming the ferrite film on the inner surface of the recirculation pipe 22 is to suppress the deposition of the radionuclides onto the inner surface, when the ferrite film is to be formed, the inner surface of the recirculation pipe 22 is preferably chemically decontaminated beforehand.

The chemical decontamination in the step S2 is carried out as described in Japanese Patent Laid-open No. 2007-182604, using a known method (see Japanese Patent Laid-open No. 2000-105295). Each of the valves 34, 33, 57, 56, 55, 49, and 47 is opened and the circulation pumps 32 and 48 are driven while the other valves are closed. This circulates the water in the surge tank 31 to the recirculation pipe 22. The temperature of the circulating water is raised to approximately 90° C. by the heater 53, and then the valve 36 is opened. KMnO₄ of a required amount is supplied from the hopper linked to the ejector 37 and introduced into the surge tank 31 through the pipe 70 to be dissolved in water there. An oxidation decontamination solution (a KMnO₄ solution) produced in the surge tank 31 is pressurized by operation of the circulation pump 32 and supplied into the recirculation pipe 22 through the film-forming solution pipe 35. The oxidation decontamination solution oxidizes and dissolves contaminations such as an oxide film formed on the inner surface of the recirculation pipe 22.

After the oxidation decontamination is finished, oxalic acid is injected into the surge tank 31 from the above hopper. This oxalic acid resolves the KMnO₄. Then, a reduction decontamination solution (an oxalic acid solution) produced in the surge tank 31 and adjusted in pH, is pressurized by operation of the circulation pump 32 and supplied to the recirculation pipe 22 through the film-forming solution pipe 35. Corrosion products on the inner surface of the recirculation pipe 22 are removed by the reduction decontamination solution. The pH of the reduction decontamination solution is adjusted by hydrazine supplied into the film-forming solution pipe 35 from the bath tank 40. A part of the reduction decontamination solution ejected from the recirculation pipe 22 is introduced to the cation resin tower 60 to remove positive metal ions.

After the reduction decontamination is finished, a part of the reduction decontamination solution flowing inside the film-forming solution pipe 35 is supplied to the decomposition apparatus 64. The oxalic acid and hydrazine contained in this reduction decontamination solution are resolved by the action of hydrogen peroxide introduced from the bath tank 46 to the decomposition apparatus 64 through the pipe 75 and by the action of active carbon catalyst in the decomposition apparatus 64. After the oxalic acid and hydrazine are resolved, the valve 55 is closed to stop heating by the heater 53. At the same time, the valve 59 is opened to cool the decontamination solution with the cooler 58. The cooled decontamination solution (for example, to 60° C.) is supplied to the mixed resin tower 62 to remove impurities.

When a ferrite film is to be formed inside a pipe (a recirculation pipe, a feed water pipe, etc.) of a newly built plant, for example, a newly built BWR plant, the chemical decontamination process in the step S2 is not necessary.

After the chemical decontamination of the recirculation pipe 22 is finished, a ferrite film forming process is executed.

After the decontamination of the film-forming object region is finished, the temperature of the film forming solution is adjusted (step S3). After the decontamination of the film-forming object region is finished, that is, after the last clean-up operation by the film formation apparatus 30 is finished, the following valve operations are performed. The valve 50 is opened and the valve 49 is closed to start passing water to a filter 51. The valve 56 is opened and the valve 63 is closed to stop passing water to the mixed resin tower 62. In addition, the valve 55 is opened, and the water in the film-forming solution pipe 35 is heated to a predetermined temperature by the heater 53. The valves 47, 57, 33, and 34 are open, and the valves 36, 59, 61, 65, 38, 41, 42, and 54 are closed. The passing of water to the filter 51 is to remove minute solids that remained in the water. If these solids remain in the water, a ferrite film is formed on the surface of these solids as well during the ferrite film formation on the film-forming object region, wasting agents. The agents contained in the film forming solution can be effectively used by removing the above solids. Supplying the film forming solution to the filter 51 during the chemical decontamination is not appropriate because the pressure loss of the filter 51 may rise due to the hydroxide caused by iron in high-concentration, occurring by dissolution. In addition, the valve 56 is opened and the valve 63 is closed to stop passing water to the mixed resin tower 62 that has been used for the clean-up operation.

A predetermined temperature for the film forming solution is preferably around 90° C. and the temperature of the film forming solution supplied to the recirculation pipe 22 is adjusted to 90° C. by the heater 53, but not limited to this temperature. It is fine as long as the film components, such as ferrite film crystals, could be formed closely packed enough for the film to suppress the deposition of the radionuclides on the inner surface of the recirculation pipe 22 made of stainless steel, during the reactor operation. Thus, the temperature of the film forming solution is preferably 200° C. or lower. Although the lowest limit of the temperature of the film forming solution could be 20° C., it is preferably 60° C. or higher at which temperatures, the velocity of the ferrite film generation is practical. At a temperature higher than 100° C., the film forming solution must be pressurized to prevent boiling, which requires a pressure system in the temporary equipment. This is not preferable since the equipment must be made in large-scale. Therefore, the temperature of the film forming solution in the film forming process is preferably adjusted to a temperature in a range of 60° C. to 100° C.

In order not to oxidize the iron (II) ions contained in the first agent, which can produce Fe(OH)₃, the oxygen dissolved in the film forming solution must be removed. For this reason, bubbling of an inert gas or vacuum degassing is preferable in the surge tank 31 and the bath tank 45.

A pH adjustment agent (the third agent) is injected in the film forming solution (step S4). By opening the valve 38 and driving the injection pump 39, a pH adjustment agent (for example, hydrazine) is injected from the bath tank 40 to the film forming solution (water when the pH adjustment agent is first injected) at a predetermined temperature (for example, 90° C.), flowing in the film-forming solution pipe 35. A pH meter (a pH measurement apparatus) 76 is installed to the film-forming solution pipe 35 downstream of the third connection point 79. The pH meter 76 measures the pH of the film forming solution flowing in the film-forming solution pipe 35. A control device (not shown) adjusts the rotational speed of the injection pump 39 (or the degree of the opening of the valve 38) based on this measured pH value, and adjusts the pH of the film forming solution to, for example, 7.0 within a range of 6.0 to 9.0.

The bath containing iron (II) ions (the first agent) is injected in the film forming solution (step S5). The valve 41 is opened and the injection pump 43 is driven to inject the bath (the first agent) containing iron (II) ions and formic acid from the bath tank 45 into the film forming solution containing hydrazine, flowing inside the film-forming solution pipe 35. The first agent injected here contains iron (II) ions prepared by, for example, dissolving iron in formate acid. A part of the iron (II) ions injected will become Fe(OH)₂ in the film forming solution.

An oxidant is injected into the film forming solution (step S6). The valve 42 is opened and the injection pump 44 is driven to inject hydrogen peroxide, which is an oxidant, from the bath tank 46 into the film forming solution containing hydrazine, iron (II) ions, and Fe(OH)₂, flowing inside the film-forming solution pipe 35. As an oxidant besides hydrogen peroxide, an agent in which O₃ or O₂ is dissolved may be used.

Since the circulation pumps 32 and 48 are driven, the film forming solution with a pH of 7.0, containing hydrazine, iron (II) ions, Fe(OH)₂, and hydrogen peroxide is supplied into the recirculation pipe 22 through the film-forming solution pipe 35 and the valve 34. This film forming solution flows inside the recirculation pipe 22; returns to the valve 47 side of the film-forming solution pipe 35; supplied with hydrazine, the agent containing iron (II) ions and formate acid, as well as hydrogen peroxide; and introduced again into the recirculation pipe 22. The film-forming aqueous solution (the film forming solution) contacts the inner surface of the recirculation pipe 22, and the iron (II) ions are adsorbed on the inner surface of the recirculation pipe 22 made of a stainless steel member. The adsorbed iron (II) ions become ferrite by the action of hydrogen peroxide. The Fe(OH)₂ in the film forming solution reacts with the hydrogen peroxide and produces magnetite. This magnetite is adsorbed on the inner surface of the recirculation pipe 22 through interface reaction. As described above, a ferrite film having magnetite as its major constituent (hereinafter referred to as a magnetite film) is formed on the inner surface of the recirculation pipe 22 contacting the film forming solution. In other words, the inner surface of the recirculation pipe 22 contacting the film forming solution is covered with the magnetite film.

The steps S4, S5, and S6 are preferably performed in sequence. To be more specific, it is preferable to start the injection of the agent containing iron (II) ions into the film forming solution when the film forming solution injected with the pH adjustment agent at the first connection point 77 reaches the second connection point 78. It is preferable to immediately perform the injection of the oxidant into the film forming solution when the film forming solution containing the pH adjustment agent and the iron (II) ions reaches the third connection point 79.

The oxidization reaction of the iron (II) ions starts as soon as the oxidant is supplied to the film forming solution containing the iron (II) ions, which makes an existence ratio of the iron (II) ions to iron (III) ions in the film forming solution suitable for the formation reaction of a ferrite film. In the film forming solution, the iron (II) ions and Fe(OH)₂ exist maintaining equilibrium. For this reason, when the iron (II) ions in the film forming solution are decreased, the Fe(OH)₂ in the film forming solution supplies iron (II) ions. In order to prevent wasteful magnetite film formation on the inner surface of the film-forming solution pipe 35, the injection point of the oxidant into the film-forming solution pipe 35 is preferably near the recirculation pipe 22, which is the film-forming object region, that is, near the connection point of the valve 34 and the film-forming solution pipe 35.

The amount of the formed ferrite film on the film-forming object region is measured (step S7). While the film forming solution is supplied to the recirculation pipe 22 through the film-forming solution pipe 35, and a magnetite film is being formed on the inner surface of the recirculation pipe 22, a surface of the metal member 18 of the quartz crystal electrode apparatus 16 disposed inside the valve bonnet 28 is also contacting the film forming solution containing iron (II) ions, hydrogen peroxide, and hydrazine as well, and having pH of 7.0. For this reason, a magnetite film is formed on the surface of the metal member 18 made of the same material as the recirculation pipe 22, in the same manner as on the inner surface of the recirculation pipe 22. The thickness of the magnetite film formed on the surface of the metal member 18 is substantially the same as the thickness of the magnetite film formed on the inner surface of the recirculation pipe 22. The thickness of the magnetite film formed on the inner surface of the recirculation pipe 22 can be obtained by measuring the thickness of the magnetite film formed on the surface of the metal member 18.

Measuring the thickness of the magnetite film formed on the surface of the metal member 18 of the quartz crystal electrode apparatus 16 is described in detail. While the film forming solution is supplied to the recirculation pipe 22, voltage is applied from a power supply included in a film-thickness calculation apparatus 29 to the quartz crystal 17 through one wiring 83. The quartz crystal 17 vibrates because of this voltage application. The metal member 18 also vibrates with the quartz crystal 17. The frequencies of the quartz crystal 17 and the metal member 18 are transmitted to the film-thickness calculation apparatus 29 through another wiring 83 connected to the quartz crystal 17. As the thickness of the magnetite film formed on the surface of the metal member 18 increases, the metal member 18 becomes heavier. Consequently, the frequency of the quartz crystal 17 including the metal member 18 becomes lower than the frequency of the quartz crystal 17 including the metal member 18 when the metal member 18 was not contacting the film forming solution, that is, when the magnetite film was not formed on the surface of the metal member 18. The difference between these frequencies represents an increase in a weight of the metal member 18 increased by the magnetite film formation on the surface of the metal member 18. Based on the inputted frequencies, the film-thickness calculation apparatus 29 calculates the difference between the frequencies, that is, the increase in the weight of the metal member 18 by the magnetite film formation. This increase in weight is the weight of the magnetite film formed on the surface of the metal member 18.

The film-thickness calculation apparatus 29 calculates the thickness of the magnetite film on the surface of the metal member 18 based on the calculated weight of the magnetite film. This thickness of the magnetite film is calculated as follows by the film-thickness calculation apparatus 29. The film-thickness calculation apparatus 29 calculates the volume of the magnetite film formed on the surface of the metal member 18 by dividing the calculated weight of the magnetite film by the density of the magnetite film. The film-thickness calculation apparatus 29 calculates the thickness of the magnetite film formed on the surface of the metal member 18 by dividing the obtained volume of the magnetite film by the area of the surface, on which the magnetite film was formed, of the metal member 18. The thickness of the magnetite film formed on the surface of the metal member 18 is, as described above, continuously measured by the film-thickness calculation apparatus 29 while the film forming solution is supplied to the recirculation pipe 22.

Whether the ferrite film forming process is completed or not is determined (step S8). The thickness of the magnetite film formed on the surface of the metal member 18, calculated by the film-thickness calculation apparatus 29, is inputted to a control device 84, and compared with a set thickness of the magnetite film. The set thickness of the magnetite film is a thickness of the magnetite film that should be formed on the inner surface of the recirculation pipe 22. When the control device 84 determines the former calculated thickness of the magnetite film is less than the latter set thickness of the magnetite film (the determination result of the step S8 is “NO”), the processes from the steps S3 to S8 are repeated. When the former calculated thickness of the magnetite film is the same as the latter set thickness of the magnetite film, the control device 84 stops the injection pumps 39, 43, and 44. This stops the supply of the bath containing iron (II) ions, the oxidant, and the pH adjustment agent into the film-forming solution pipe 35, and the magnetite film forming operations are ended. Instead of stopping the injection pumps 39, 43, and 44, the valves 38, 41, and 42 may be closed by the control device 84.

When the thickness of the magnetite film formed on the surface of the metal member 18, calculated by the film-thickness calculation apparatus 29, reaches the set thickness of the magnetite film, an operator may stop the operation of the injection pumps 39, 43, and 44. In this case, the control device is not needed. The thickness of the magnetite film formed on the surface of the metal member 18, calculated by the film-thickness calculation apparatus 29, is displayed on a display device, and by looking at the thickness displayed on the display device, the operator determines whether to stop the operation of the injection pumps 39, 43, and 44. When the displayed thickness reaches the set thickness, the operator can stop the injection pumps 39, 43, and 44 as described above.

In order to stop the magnetite film formation on the inner surface of the recirculation pipe 22, the operation of the injection pumps 43 and 44 can be stopped to stop the injections of the agent containing iron (II) ions, and the oxidant into the film forming solution. Instead of stopping the injection pumps 43 and 44, the valves 41 and 42 may be closed. Stopping the injection pump 39 at the end of the magnetite film forming operations prevents extra hydrazine from being injected into the film forming solution, which can shorten the time required for resolving hydrazine in step S9 to be given later.

After the magnetite film forming operations are finished, the agents contained in the film forming solution are resolved (step S9). The film forming solution used for the magnetite film formation on the inner surface of the recirculation pipe 22 contains hydrazine and formate acid, which is organic acid, even after the magnetite film formation is finished. The hydrazine and formic acid contained in the film forming solution are resolved in the decomposition apparatus 64 in the same manner as the decomposition of oxalic acid, which is a reduction decontamination agent. In the decomposition process of the agents, each the degree of the opening of the valves 57 and 65 is adjusted and a part of the film forming solution in the film-forming solution pipe 35 is supplied to the decomposition apparatus 64. By opening the valve 54, hydrogen peroxide is supplied from the bath tank 46 to the decomposition apparatus 64 through the pipe 75. Hydrazine and formate acid are resolved in the decomposition apparatus 64 by the action of the hydrogen peroxide and active carbon catalyst. Hydrazine is resolved into N₂ and water, and formate acid into carbon dioxide and water. It is possible to use an ultraviolet exposure apparatus in place of the decomposition processing apparatus 64 using a catalyst. The ultraviolet exposure apparatus can also resolve hydrazine, formate acid, and oxalic acid in the presence of an oxidant.

Resolving hydrazine and formate acid into gas and water in the decomposition apparatus 64 as described above allows the removal of hydrazine in the cation resin tower 60 and the removal of formate acid in the mixed resin tower 62 to be avoided. Thus, the waste amount of the used ion-exchange resin in the cation resin tower 60 can be significantly reduced.

According to the present embodiment, since the quartz crystal electrode apparatus 16 disposed in the film-forming solution pipe 35 detects the thickness of a magnetite film formed on the inner surface of the recirculation pipe 22, which is the film-forming object region, this thickness can be measured while the film forming solution is supplied to the recirculation pipe 22. In addition, the measurement results of the thickness can be continuously obtained during the supply of the film forming solution. For this reason, in the present embodiment, as soon as the thickness of the magnetite film being measured by the quartz crystal electrode apparatus 16 reaches the set thickness during the supply of the film forming solution to the recirculation pipe 22, at least the supplies of the agent containing iron (II) ions, and the oxidant into the film-forming solution pipe 35 can be stopped. This completes the magnetite film forming operations on the inner surface of the recirculation pipe 22. The present embodiment such as this can shorten the time required from the start to the end of the ferrite film forming operations. Furthermore, in the present embodiment, whether or not the magnetite film of a set thickness is formed on the inner surface of the recirculation pipe 22, which is the film-forming object, can be checked.

In the present embodiment, the film forming solution with a pH within a range of 6.0 to 9.0, including the agent containing iron (II) ions, and the oxidant, is supplied into the recirculation pipe 22, so that a close ferrite film can be formed on all the inner surfaces of the recirculation pipe 22 contacting the film forming solution. For this reason, deposition of radioactive nuclides on the inner surface of the recirculation pipe 22 contacting the cooling water during the operation of the BWR plant can be inhibited.

Although the present embodiment uses the quartz crystal electrode apparatus 16 for continuously measuring the amount of the formed ferrite film, any measuring method that can continuously measure the amount of the formed ferrite film, for example, an electrochemical method such as an AC impedance method, may be used in place of the quartz crystal electrode apparatus 16.

### Embodiment 2

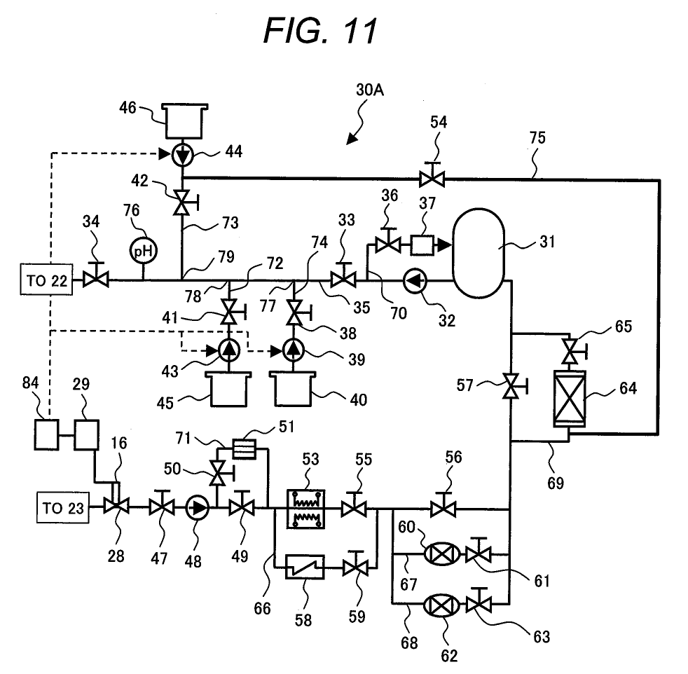

A method for forming a ferrite film onto a surface of a structural member composing a nuclear power plant, applied to a recirculation pipe of a BWR plant, according to embodiment 2 which is another embodiment of the present invention, is described below with reference to FIG. 11. A film formation apparatus 30A used in the method for forming a ferrite film according to the present embodiment is different from the film formation apparatus 30 in that the valve bonnet 28 installed with the quartz crystal electrode apparatus 16 is provided to the film-forming solution pipe 35 upstream of the opening/closing valve 47. The other structure of the film formation apparatus 30A is the same as the film formation apparatus 30. In the present embodiment, a magnetite film is formed on the inner surface of the recirculation pipe 22 using the film formation apparatus 30A in the same manner as in the embodiment 1.

A magnetite film is formed on the surface of the metal member 18 of the quartz crystal electrode apparatus 16 contacting the film forming solution. The film forming solution returned to the film-forming solution pipe 35 from the recirculation pipe 22 contains iron (II) ions, hydrogen peroxide, and hydrazine, each of which is reduced in concentration than that in the film forming solution supplied to the recirculation pipe 22. Due to the actions of these substances, a magnetite film is formed on the surface of the metal member 18 of the film formation apparatus 30A.

In the present embodiment, when the thickness of the magnetite film calculated by the film-thickness calculation apparatus 29 reaches the set thickness, the control device 84 stops the injection pumps 39, 43, and 44. By the time the thickness of the magnetite film calculated by the film-thickness calculation apparatus 29 reaches the set thickness, the thickness of the magnetite film formed on the inner surface of the recirculation pipe 22, which is the film-forming object, has become equal to or more than the set thickness. In such a present embodiment, each effect attained in the embodiment 1 can be obtained.

In the present embodiment, another valve bonnet 28 installed with another quartz crystal electrode apparatus 16 may be additionally disposed to the film-forming solution pipe 35 downstream of the third connection point 79 as in embodiment 1. In this case, the frequency of the quartz crystal 17 of another quartz crystal electrode apparatus 16 provided to another valve bonnet 28 is also inputted into the above-mentioned film-thickness calculation apparatus 29 to calculate the thickness of the magnetite film formed on the surface of the metal member 18 of another quartz crystal electrode apparatus 16.

### Embodiment 3

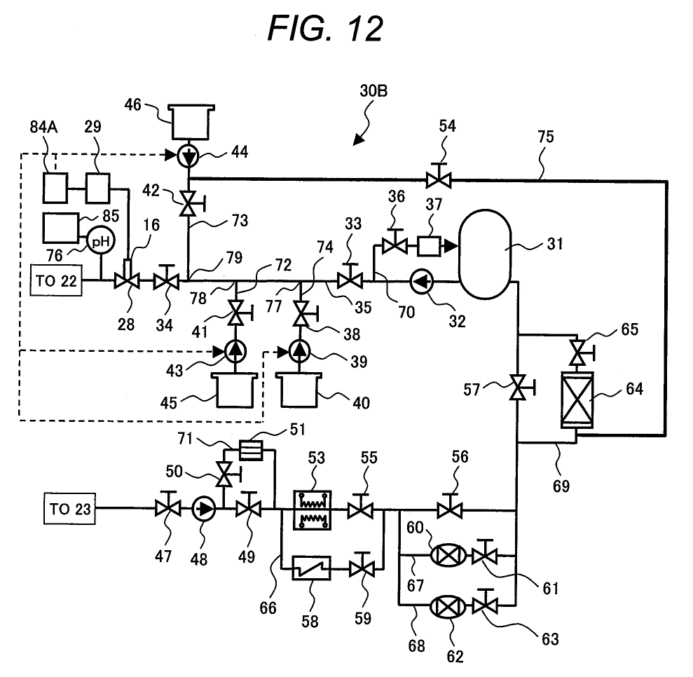

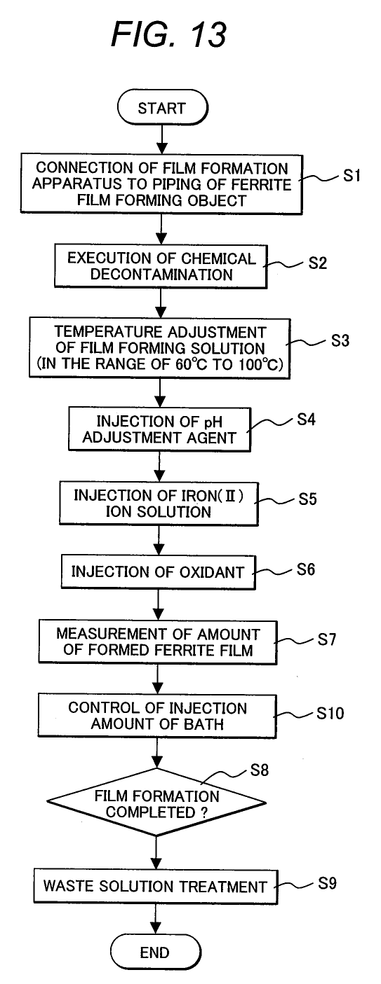

A method of forming a ferrite film on a surface of a structural member composing a nuclear power plant, applied to a recirculation pipe of a BWR plant, according to embodiment 3 which is another embodiment of the present invention, is described below with reference to FIGS. 12 and 13. A film formation apparatus 30B used in the present embodiment has a control device 84A in place of the control device 84 in the film formation apparatus 30 (see FIG. 12). The other structure of the film formation apparatus 30B is the same as the film formation apparatus 30. The film formation apparatus 30B has a pH control device 85. This pH control device 85 is also provided to the film formation apparatuses 30 and 30A.

In the method for forming a ferrite film onto a surface of a structural member composing a nuclear power plant according to the present embodiment, each operation and process of the steps S1 to S9 executed in the embodiment 1 is performed. In the present embodiment, the injection amounts of the baths are controlled (step S10) between the steps S7 and S8. The injection amounts of the baths are controlled as follow.

In the step S7, as described above, the amount of ferrite film formation is measured. In other words, the film-thickness calculation apparatus 29 calculates the thickness of a magnetite film formed on the surface of the metal member 18 contacting the film forming solution based on the frequencies of the quartz crystal 17 and the metal member 18 of the quartz crystal electrode apparatus 16. The calculated thickness of the magnetite film is inputted in the control device 84A. The control device 84A calculates the velocity of the magnetite film formation based on the thicknesses of the magnetite film continuously inputted from the film-thickness calculation apparatus 29, and determines whether or not the velocity of the film formation calculated is a target velocity for film formation.

When the calculated velocity of the film formation is off from the target velocity of the film formation, the control device 84A controls the rotational speeds of the injection pumps 43 and 44 to adjust the injection amounts of the bath containing iron (II) ions, and the hydrogen peroxide into the film-forming solution pipe 35. For example, when the calculated velocity of the film formation is lower than the target velocity of the film formation, the rotational speeds of the injection pumps 43 and 44 are raised to increase the injection amounts of the bath containing iron (II) ions, and the hydrogen peroxide into the film-forming solution pipe 35. This increase in the injection amounts reduces the pH of the film forming solution flowing in the film-forming solution pipe 35. When the pH of the film forming solution measured by the pH meter 76 goes lower than a set pH value, the pH control device (another control device) 85 increases the rotational speed of the injection pump 39 to increase the injection amount of hydrazine to maintain the pH of the film forming solution to the set pH value (7.0 for example, in a range of 6.0 to 9.0). By controlling the injection pumps 43 and 44 as described above, the velocity of the magnetite film formation on the inner surface of the recirculation pipe 22 is increased and the target velocity of the film formation is maintained.

When the calculated velocity of the film formation is higher than the target velocity of the film formation, the control device 84A conversely reduces the rotational speed of the injection pumps 43 and 44 to decrease the injection amounts of the bath containing ion (II) irons, and the hydrogen peroxide into the film-forming solution pipe 35. The pH of the film forming solution goes up, so that the pH control device 85 reduces the rotational speed of the injection pump 39 to decrease the injection amount of hydrazine, and maintains the pH of the film forming solution to the set pH value. By controlling the injection pumps 43 and 44 in such way, the velocity of the magnetite film formation on the inner surface of the recirculation pipe 22 is reduced, and the target velocity of the film formation is maintained.

When the control device 84A determines that the thickness of the magnetite film formed on the surface of the metal member 18, calculated by the film-thickness calculation apparatus 29, has reached the set thickness (step S8), the control device 84A stops the injection pumps 39, 43, and 44 in the same manner as in the embodiment 1.

In the present embodiment, each effect attained in the embodiment 1 can also be obtained.

In addition, in the present embodiment, since the amount of the formed magnetite film can be controlled based on the measured thickness of the magnetite film, the magnetite film having the set thickness can be formed in a shorter period of time. When the calculated velocity of the film formation is lower than the target velocity of the film formation, the injection amounts of the agent containing iron (II) ions, and the oxidant, for example, hydrogen peroxide, into the film-forming solution pipe 35 are increased. This raises the velocity of the film formation to the target velocity of the film formation, thus the magnetite film of the set thickness can be formed in a shorter period of time. When the calculated velocity of the film formation is higher than the target velocity of the film formation, the velocity of the film formation is reduced to the target velocity of the film formation, thus the magnetite film of the set thickness can be formed in a shorter period of time.

When the injection amounts of the agent containing iron (II) ions, and the oxidant into the film-forming solution pipe 35 become excessive, cores that can grow into magnetite occur in the film forming solution besides the magnetite film formation on the inner surface of the recirculation pipe 22, followed by waste magnetite particles formed around those cores in the film forming solution. This reduces the velocity of the magnetite film formation on the inner surface of the recirculation pipe 22, causing the magnetite film formation on the inner surface to take a longer time. The target velocity of the film formation is set to avoid a situation such as the agent containing iron (II) ions, and the oxidant are excessively injected into the film-forming solution pipe 35 until they reduce the velocity of the film formation. Therefore, when the calculated velocity of the film formation is higher than the target velocity of the film formation, the velocity of the film formation is reduced to the target velocity of the film formation, so that the magnetite film of the set thickness can be formed in a shorter period of time.

In the present embodiment, since the quartz crystal electrode apparatus 16 is disposed to the supply side of the film-forming solution pipe 35 where the film forming solution is supplied to the recirculation pipe 22, the velocity of the film formation can be quickly obtained at an earlier stage than the film formation on the inner surface of the recirculation pipe 22. This allows the injection amounts of the agent including iron (II) ions, and the oxidant to be controlled ahead of time, and the velocity of the film formation on the inner surface of the recirculation pipe 22 can be adjusted sooner.

In the present embodiment, the valve bonnet 28 installed with the quartz crystal electrode apparatus 16 may be provided to the film-forming solution pipe 35 not downstream of the opening/closing valve 41, but upstream of the opening/closing valve 47 as in the embodiment 2. The value bonnet 28 installed with the quartz crystal electrode apparatus 16 may be disposed to two places—upstream of the opening/closing valve 47 and downstream of the opening/closing valve 41.

### Embodiment 4

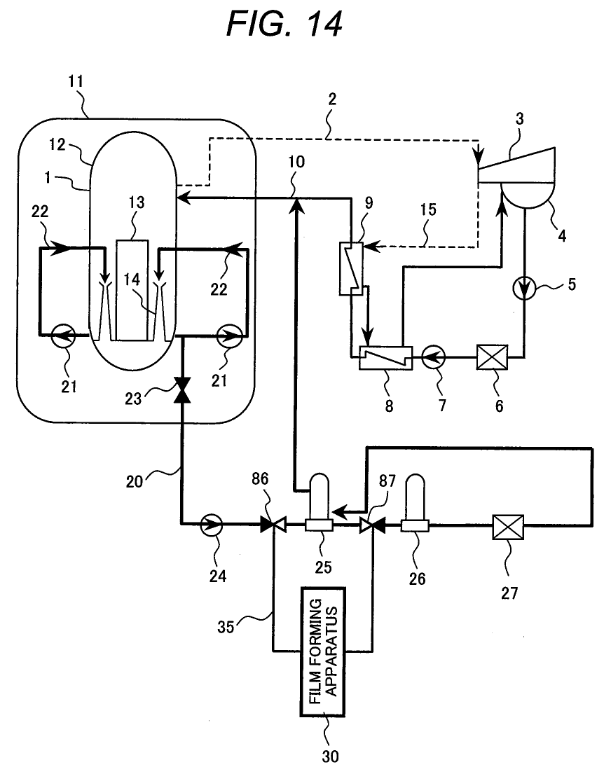

A method of forming a ferrite film on a surface of a structural member composing a nuclear power plant, applied to a clean-up pipe 20 of a BWR plant, according to embodiment 4 which is another embodiment of the present invention, is described below with reference to FIG. 14. In a reactor clean-up system, a corrosion problem arises in the regenerative heat exchanger 25 into which the cooling water of a high temperature flows from the RPV 12, and in the clean-up pipe 20 around the regenerative heat exchanger 25. The clean-up pipe 20 is made of carbon steel. Valves 86 and 87 are provided to the clean-up pipe 20 upstream and downstream of the regenerative heat exchanger 25 respectively.

The bonnet of the valve 86 is opened and one end of the film-forming solution pipe 35 of the film formation apparatus 30 is connected to a flange on the opened bonnet of the valve 86. The valve 23 is closed. The bonnet of the valve 87 is opened and a flange on the non-regenerative heat exchanger 26 side is blocked. The other end of the film-forming solution pipe 35 of the film formation apparatus 30 is connected to a flange on the opened bonnet of the valve 87. In this way, the film formation apparatus 30 is connected to the clean-up pipe 20, and a circulation passage of the clean-up pipe 20 and the film-forming solution pipe 35 for the film forming solution is formed.

In the present embodiment also, each operation and process of the steps S1 to S9 in the embodiment 1 is executed. In the present embodiment, the metal member 18 of the quartz crystal electrode apparatus 16 is made of the same carbon steel material as the clean-up pipe 20. In the present embodiment also, a magnetite film is formed on the inner surfaces of the clean-up pipe 20 and the regenerative heat exchanger 25, contacting the film forming solution. Among the structural members of the reactor clean-up system, the surfaces of the structural members contacting the film forming solution are covered with the magnetite film.

In the present embodiment also, each effect attained in the embodiment 1 can be obtained. In the present embodiment, since the surfaces of carbon steel members contacting the cooling water can be covered with close magnetite films, corrosion of the carbon steel members composing a nuclear power plant can be inhibited.

When no valve 87 exists between the regenerative heat exchanger 25 and the non-regenerative heat exchanger 26, the other end of the film-forming solution pipe 35 of the film formation apparatus 30 may be connected to an isolation valve provided to the clean-up pipe 20 between the non-regenerative heat exchanger 26 and the reactor water clean-up apparatus 27.

In the present embodiment, the above-described film formation apparatus 30A or 30B may be used in place of the film formation apparatus 30. When the film formation apparatus 30B is used, each operation and process of the steps S1 to S10 shown in FIG. 13 is executed.

Each of the methods for forming a ferrite film onto a surface of a structural member composing a plant according to the embodiments 1, 2, and 3 can be applied to a carbon steel feed water pipe in a BWR plant, a carbon steel feed water pipe in a PWR plant, a carbon steel feed water pipe in a thermal plant, and a stainless steel primary coolant pipe in a PWR plant. The primary coolant pipe in the PWR plant supplies cooling water of a high temperature generated in the reactor pressure vessel to a steam generator, and returns the cooled cooling water ejected from the steam generator back to the reactor pressure vessel.

When a ferrite film is to be formed onto the inner surface of the carbon steel feed water pipe 10 contacting feed water in a BWR plant, both ends of the film-forming solution pipe 35 of any of the film formation apparatuses 30, 30A, and 30B can be connected to the feed water pipe 10 as shown in FIG. 4 of Japanese Patent Laid-open No. 2007-182604. Furthermore, when a ferrite film is to be formed onto the inner surface of a feed water pipe contacting feed water in a PWR plant, both ends of the film-forming solution pipe 35 of any of the film formation apparatuses 30, 30A, and 30B can be connected to the feed water pipe as shown in FIG. 8 of Japanese Patent Laid-open No. 2007-182604. When a ferrite film is to be formed on the inner surface of a feed water pipe contacting feed water in a thermal plant, both ends of the film-forming solution pipe 35 of any of the film formation apparatuses 30, 30A, and 30B can be connected to the feed water pipe as shown in FIG. 9 of Japanese Patent Laid-open No. 2007-182604. When a ferrite film is to be formed on the inner surface of a primary coolant pipe contacting the cooling water in a PWR plant, an isolation valve of the primary coolant pipe, provided in the vicinity of the reactor pressure vessel, can be closed to prevent the film forming solution from flowing into the reactor pressure vessel, and the film forming solution can be supplied into the primary coolant pipe using any of the film formation apparatuses 30, 30A, and 30B.

What is claimed is:

1. A method for forming a ferrite film onto surface of structural member composing a plant, comprising steps of:
forming a ferrite film onto the wetted surface of the structural member by making contact with a film forming solution containing iron (II) ions, an oxidant for oxidizing the iron (II) ions, and a pH adjustment agent;
measuring the amount of the formed ferrite film; and
determining completion of the ferrite film formation based on the measured amount of the formed ferrite film.

2. The method for forming a ferrite film onto surface of structural member composing a plant according to claim 1, wherein injections of a liquid containing the iron (II) ions, and the oxidant into the film forming solution are stopped when it is determined based on the measured amount of the ferrite film formation that the ferrite film formation is to be completed.

3. The method for forming a ferrite film onto surface of structural member composing a plant according to claim 2, wherein injection of the pH adjustment agent into the film forming solution is stopped based on the measured amount of the ferrite film formation.

4. The method for forming a ferrite film onto surface of structural member composing a plant according to claim 2, wherein the injections of the liquid containing the iron (II) ions, and the oxidant are stopped when a thickness of the ferrite film obtained based on the measured amount of the formed ferrite film reaches a set thickness.

5. The method for forming a ferrite film onto surface of structural member composing a plant according to claim 2, wherein injection amounts of the liquid containing the iron (II) ions, and the oxidant into the film forming solution are controlled based on the measured amount of the formed ferrite film.

6. The method for forming a ferrite film on surface of structural member composing a plant according to claim 5, wherein the injection amounts of the liquid containing the iron (II) ions, and the oxidant into the film forming solution are controlled so that velocity of the film formation obtained based on the measured amount of the formed ferrite film reaches a set velocity of the film formation.

7. The method for forming a ferrite film onto surface of structural member composing a plant according to claim 1, wherein the measured amount of the formed ferrite film is amount of a ferrite film formed on a surface, with which the film forming solution contacts with, of a metal member of a quartz crystal electrode apparatus soaked in the film forming solution.

8. The method for forming a ferrite film onto surface of structural member composing a plant according to claim 7, wherein the metal member is made of the same material as the structural member composing the plant.

9. A method for forming a ferrite film onto surface of structural member composing a plant, comprising steps of:
connecting a film-forming solution pipe for supplying a film forming solution containing iron (II) ions, an oxidant for oxidizing the iron (II) ions, and a pH adjustment agent, into a film-forming object pipe of the plant, being the structural member;
forming the ferrite film onto a inner surface, with which the film-forming solution contacts, of the film-forming object pipe by supplying the film forming solution to the film-forming object pipe through the film-forming solution pipe;
measuring amount of the ferrite film formed on a surface, with which the film forming solution contacts, of a metal member provided to a film-forming amount measurement apparatus by the film-forming amount measurement apparatus; and
stopping injections of a liquid containing the iron (II) ions, and the oxidant into the film forming solution based on the measured amount of the formed ferrite film.

10. The method for forming a ferrite film onto surface of structural member composing a plant according to claim 9, comprising further steps of:
forming a closed loop including the film-forming solution pipe and the film-forming object pipe by connecting both ends of the film-forming solution pipe to the film-forming object pipe; and
performing the measurement of the amount of the formed ferrite film by the film-forming amount measurement apparatus by making at least one of the film forming solution supplied to the film-forming object pipe and the film forming solution returned from the film-forming object pipe contact with the metal member.

11. The method for forming a ferrite film onto surface of structural member composing a plant according to claim 9, wherein the injections of the liquid containing the iron (II) ions, and the oxidant are stopped when a thickness of the ferrite film on the surface of the metal member, obtained based on the measured amount of the formed ferrite film, reaches a set thickness.

12. The method for forming a ferrite film on surface of structural member composing a plant according to claim 9, wherein injection amounts of the liquid containing the iron (II) ions, and the oxidant into the film forming solution are controlled based on the measured amount of the formed ferrite film.

13. The method for forming a ferrite film on surface of structural member composing a plant according to claim 9, wherein a metal member provided to a quartz crystal electrode apparatus is used as the metal member of the film-forming amount measurement apparatus.

14. The method for forming a ferrite film onto surface of structural member composing a plant according to claim 9, wherein the film-forming object pipe is a feed water pipe of the plant.

15. The method for forming a ferrite film onto surface of structural member composing a plant according to claim 9, wherein the film-forming object pipe is a pipe connected to a nuclear reactor of a nuclear power plant, for passing coolant from the reactor.

16. The method for forming a ferrite film onto surface of structural member composing a plant according to claim 1, wherein injection amounts of a liquid containing the iron (II) ions, and the oxidant into the film forming solution are controlled based on the measured amount of the formed ferrite film.

17. The method for forming a ferrite film onto surface of structural member composing a plant according to claim 16, comprising further steps of:
measuring pH of the film forming solution; and
controlling injection amount of the pH adjustment agent into the film forming solution based on the measured pH value.

18. The method for forming a ferrite film onto surface of structural member composing a plant according to claim 16, wherein the injection amounts of the liquid containing the iron (II) ions, and the oxidant into the film forming solution are controlled so that a velocity of the film formation obtained based on the measured amount of the formed ferrite film reaches a set velocity of the film formation.

19. The method for forming a ferrite film onto surface of structural member composing a plant according to claim 16, wherein the measured amount of the formed ferrite film is amount of a ferrite film formed on a surface, with which the film forming solution contacts, of a metal member of a quartz crystal electrode apparatus soaked in the film forming solution.

20. The method for forming a ferrite film onto surface of structural member composing a plant according to claim 19, wherein the metal member is made of the same material as the structural member composing the plant.

21. The method for forming a ferrite film on surface of structural member composing a plant according to claim 16, comprising further steps of:
connecting a film-forming solution pipe for supplying the film forming solution to a film-forming object pipe of the plant, being the structural member composing the plant;
forming the ferrite film onto a inner surface, with which the film forming solution contacts, of the film-forming object pipe by supplying the film forming solution to the film-forming object pipe though the film-forming solution pipe; and
measuring amount of the ferrite film formed on a surface, with which the film forming solution contacts, of a metal member provided to a film-forming amount measurement apparatus by the film-forming amount measurement apparatus.

22. The method for forming a ferrite film onto surface of structural member comprising a plant according to claim 21, comprising further steps of:
forming a closed loop including the film-forming solution pipe and the film-forming object pipe by connecting both ends of the film-forming solution pipe to the film-forming object pipe; and
performing the measurement of the amount of the formed ferrite film by the film-forming amount measurement apparatus by making at least one of the film forming solution supplied to the film-forming object pipe and the film forming solution returned from the film-forming object pipe contact with the metal member.

23. The method for forming a ferrite film onto surface of structural member composing a plant according to claim 21, wherein a metal member provided to a quartz crystal electrode apparatus is used as the metal member of the film-forming amount measurement apparatus.

24. A film formation apparatus, comprising:
a film-forming solution pipe being connected to a film-forming object pipe of a plant;
a first bath tank for storing a liquid containing iron (II) ions supplied to the film-forming solution pipe;
a second bath tank for storing an oxidant supplied to the film-forming solution pipe;
a third bath tank for storing a pH adjustment agent supplied to the film-forming solution pipe;
a heat apparatus installed to the film-forming solution pipe; and
a film-forming amount measurement apparatus installed to the film-forming solution pipe, having a metal member disposed in the film-forming solution pipe and contacting with a film forming solution containing the iron (II) ions, the oxidant, and the pH adjustment agent, flowing inside the film-forming solution pipe, and measuring amount of ferrite film being formed on a surface of the metal member.

25. The film formation apparatus according to claim 24, further comprising:
a control device for stopping supply of a liquid containing iron (II) ions, and an oxidant into the film-forming solution pipe based on the amount of the ferrite film measured by the film-forming amount measurement apparatus.

26. The film formation apparatus according to claim 24, further comprising:
a control device for controlling supply amounts of the liquid containing the iron (II) ions, and the oxidant into the film-forming solution pipe based on the amount of the ferrite film measured by the film-forming amount measurement apparatus.

27. The film formation apparatus according to claim 24, wherein the film-forming amount measurement apparatus has a quartz crystal electrode apparatus including a quartz crystal provided with the metal member, and a film-forming amount calculation apparatus for calculating the amount of the ferrite film based of frequency of the quartz crystal.

28. The film formation apparatus according to claim 27, wherein the quartz crystal electrode apparatus has the metal member, the quartz crystal, a holding member for holding the quartz crystal, and a sealing member; and
the sealing member covers all the surfaces of the quartz crystal except for the surfaces contacting the metal member and the holding member.

29. A quartz crystal electrode apparatus, comprising:
a holding member;
a quartz crystal disposed to the holding member;
a metal member installed on a surface of the quartz crystal; and
a sealing member covering all the surfaces of the quartz crystal except for the surfaces contacting the metal member and the holding member.
